(19) United States
(12) Patent Application Publication
(10) Pub. No.: US 2025/0362347 A1
(43) Pub. Date: Nov. 27, 2025

(54) SWITCH CONTROL DEVICE FOR POWER SUPPLY SYSTEM

(71) Applicant: DENSO CORPORATION, Kariya-city (JP)

(72) Inventor: Yoshinori MORITA, Kariya-city (JP)

(73) Assignee: DENSO CORPORATION, Kariya-city (JP)

(21) Appl. No.: 19/293,079

(22) Filed: Aug. 7, 2025

Related U.S. Application Data
(63) Continuation of application No. PCT/JP2024/000790, filed on Jan. 15, 2024.

(30) Foreign Application Priority Data
Feb. 10, 2023 (JP) 2023-019470

(51) Int. Cl. G01R 31/327; H02J 1/08

(52) U.S. Cl. CPC G01R 31/3277; H02J 1/084

(57) ABSTRACT

A switch control device for a power supply system equipped with a first power source and a second power source connected via an electrical pathway, an electrical load connected to the electrical pathway and capable of being supplied with power from the first power source and the second power source, and a switch provided between the second power source and a connection point along the electrical pathway where the electrical load is connected to the electrical pathway. The switch control device diagnoses an ON failure of the switch by turning off the switch. In the switch control device, a determination unit determines whether the first power source is in a power output state, and a command unit temporarily outputs an OFF-command to the switch when performing diagnosis of the ON failure, on condition that the first power source is determined to be in the power output state.

### CROSS-REFERENCE TO RELATED APPLICATION

This application is a continuation application of International Application No. PCT/JP2024/000790 filed Jan. 15, 2024 which designated the U.S. and claims priority to Japanese Patent Application No. 2023-019470 filed Feb. 10, 2023, the contents of each of which are incorporated herein by reference.

### BACKGROUND

### Technical Field

This disclosure relates to a switch control device for a power supply system.

### Related Art

Conventionally, a power supply system has been known which includes a plurality of power sources and electrical loads that are capable of receiving power supplied from each of the power sources. In such a power supply system, each electrical load is connected to an electrical pathway that connects the plurality of power sources, and a switch is provided between one of the power sources and a connection point to the electrical load. The power supply system includes technology for diagnosing whether an ON failure, in which the switch is stuck in the ON state, has occurred.

### BRIEF DESCRIPTION OF THE DRAWINGS

In the accompanying drawings:

FIG. 1 is a schematic diagram of the overall configuration of an on-board power supply system according to a first embodiment;

FIG. 2 is a flowchart illustrating process steps of control performed by a control device;

FIGS. 3A-3C are timing diagrams illustrating an example of control operation performed by the control device;

FIGS. 4A-4C are timing diagrams illustrating an example of control operation according to a modification of the first embodiment;

FIGS. 5A-5C are timing diagrams illustrating another example of control operation according to a modification of the first embodiment;

FIG. 6 is a flowchart illustrating process steps of control performed by a control device according to a modification of the first embodiment;

FIG. 7 is a schematic diagram of the overall configuration of an on-board power supply system according to a second embodiment;

FIG. 8 is a flowchart illustrating process steps of control performed by the control device; and

FIG. 9 is a schematic diagram of the overall configuration of an on-board power supply system according to a third embodiment.

### DESCRIPTION OF SPECIFIC EMBODIMENTS

In the above-mentioned known power supply systems, as disclosed in, for example, JP 2018-93694 A, a switch may be temporarily turned off when diagnosing whether an ON failure of the switch has occurred. When the switch is temporarily turned off, supply of drive power from the power source connected to the electrical load via the switch is temporarily interrupted. In this case, there is a concern that the electrical load may stop operating unintentionally.

In view of the foregoing, it is desired to have a switch control device that is capable of diagnosing whether an ON failure of a switch has occurred without interrupting the operation of electrical loads.

One aspect of the present disclosure provides a switch control device for a power supply system equipped with a first power source and a second power source connected via an electrical pathway, an electrical load connected to the electrical pathway and capable of being supplied with power from the first power source and the second power source, and a switch provided between the second power source and a connection point along the electrical pathway where the electrical load is connected to the electrical pathway. The switch control device is configured to diagnose an ON failure of the switch by turning off the switch, and includes: a determination unit configured to determine whether the first power source is in a power output state in which it is outputting power to the electrical pathway; and a command unit configured to temporarily output an OFF-command to the switch when performing diagnosis of the ON failure, on condition that the first power source is determined to be in the power output state.

In the above configuration, the switch is turned off and an ON failure of the switch is thereby diagnosed. In this case, when performing diagnosis of the ON failure of the switch, power supply from the second power source to the electrical load is temporarily interrupted, which raises a concern that the operation of the electrical load may be unintentionally suspended.

According to the present disclosure, it is determined whether the first power source is in the power output state in which electric power is supplied to the electrical pathway. When performing diagnosis of the ON failure of the switch, the OFF-command is temporarily output to the switch, on condition that the first power source is determined to be in the power output state. In this case, drive power for the electrical load is secured while the switch is off. This can prevent occurrence of an unintended power source failure of the electrical load and prevent the electrical load from stopping operation.

### First Embodiment

Hereinafter, a switch control device according to a first embodiment of the present disclosure will now be described with reference to the accompanying drawings. In the present embodiment, the switch control device is applied to an on-board power supply system. The power supply system is mounted to a motorized vehicle with a motor as a prime mover.

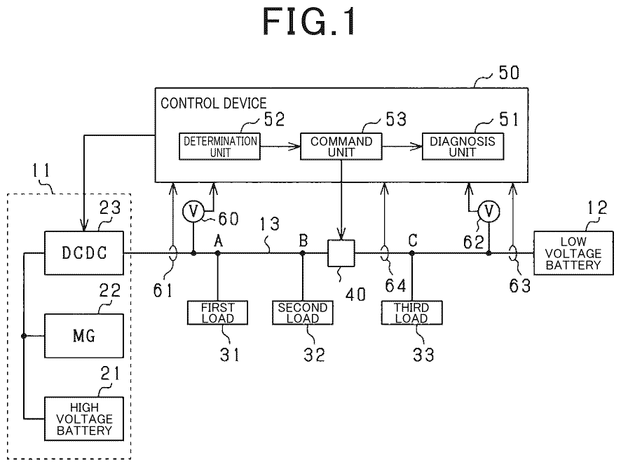

As illustrated in FIG. 1, the power supply system includes a first power source 11 and a second power source 12, which are connected to each other via an electrical pathway 13. The first power source 11 includes a high voltage battery 21, a rotating electric machine 22, and a DC-DC converter 23. The high voltage battery 21 is configured as a series connection of a plurality of battery cells, and has a rated voltage of, for example, several hundred volts. Each of the battery cells is a rechargeable battery, and specifically, a rechargeable lithium-ion battery.

The rotating electric machine 22 serves as a prime mover for the vehicle, and is supplied with electric power from the high voltage battery 21 to transmit drive force to drive wheels of the vehicle. The rotating electric machine 22 also functions as a generator that performs regenerative power generation during travel of the vehicle. The rotating electric machine 22 includes an inverter that controls current for each phase, and the inverter is connected to the high voltage battery 21. Accordingly, electric conduction between the high voltage battery 21 and the rotating electric machine 22 is enabled. The DC-DC converter 23 is connected to the high voltage battery 21, and is configured to step down the high voltage on the high voltage battery 21 side. For example, the DC-DC converter 23 steps down the high voltage on the high voltage battery 21 side to a voltage of 12 V to 14 V.

The second power source 12 is constituted by a low voltage battery. The low voltage battery has a rated voltage lower than that of the high voltage battery 21, and is, for example, 12 V. The low voltage battery is a rechargeable battery, and is, for example, a lead-acid battery or a rechargeable lithium-ion battery.

The power supply system includes a first load 31, a second load 32, and a third load 33. Each of the loads 31 to 33 is capable of receiving electric power from the first power source 11 and the second power source 12. The loads 31 to 33 are connected to connection points A, B, and C of the electrical pathway 13. Each of the loads 31 to 33 has its positive terminal side connected to the electrical pathway 13, and its negative terminal side connected to a grounded portion such as the vehicle body.

The first to third loads 31 to 33 include, for example, various types of ECUs. Each ECU includes an internal memory that stores processed information, and the memory stores information processed during the previous trip of the vehicle. Accordingly, the first to third loads 31 to 33 require a supply of dark current in order to retain stored information over an extended period of time. In addition to the ECUs, the first to third loads 31 to 33 may also include electrical loads that require a supply of dark current in order to continue at least some of their functions over an extended period of time, such as a navigation device, an anti-theft device, or a lighting device. Each of the loads 31 to 33 illustrated in FIG. 1 may be a single electrical load or may include a plurality of electrical loads.

In some embodiments, the loads 31 to 33 may be other types of electrical loads. For example, the loads 31 to 33 may be electrical loads used for driving assistance control of the vehicle. Specifically, they may include an electric power steering device that generates assist torque for assisting the steering operation by the driver, an electric brake device that applies braking force to the wheels, a camera for monitoring surroundings of the vehicle, a laser radar such as Laser Imaging Detection and Ranging (LiDAR), or a millimeter-wave radar, or an electrical load such as a steer-by-wire system, all of which are used for driving assistance control of the vehicle. Further, the loads 31 to 33 may be, specifically, general-purpose electrical loads such as an air conditioner, an audio device, or power windows, an electric fan for a radiator that cools the engine coolant, a stop lamp, interior lights, USB power sockets, and a motor for driving a mirror provided outside the vehicle cabin.

The power supply system includes an interrupt switch 40. The interrupt switch 40 is a normally-closed switch, and is configured, for example, as a relay or a semiconductor switch such as a MOSFET. The interrupt switch 40 is provided in the electrical pathway 13 between a connection point B of the second load 32 and a connection point C of the third load 33.

The power supply system includes a control device 50, a voltage sensor 60 and a current sensor 61 provided on the first power source 11 side of the interrupt switch 40, a voltage sensor 62 and a current sensor 63 provided on the second power source 12 side of the interrupt switch 40, and a switch current sensor 64. Each of the voltage sensors 60 and 62 detects a voltage on the electrical pathway 13. The current sensor 61 on the first power source 11 side detects an output current of the first power source 11. The current sensor 63 on the second power source 12 side detects an output current of the second power source 12. The switch current sensor 64 detects a current flowing through the interrupt switch 40. Each of the current sensors 61, 63, and 64 detects a current using, for example, a shunt resistor or a Hall element. The control device 50 acquires detected values from the sensors 60 to 64.

The control device 50 is mainly constituted by a microcomputer including a CPU and various types of memory. The functions provided by the control device 50 may be implemented by software stored in a tangible memory device and a computer that executes the software, by software alone, by hardware alone, or by any combination thereof.

For example, the control device 50 controls the output voltage of the DC-DC converter 23 so that the terminal voltage or the state of charge (SOC) of the low voltage battery included in the second power source 12 falls within a predefined range. When charging the low voltage battery, the control device 50 controls the output voltage of the DC-DC converter 23 to be higher than the rated voltage of the low voltage battery, and when discharging the low voltage battery, controls the output voltage of the DC-DC converter 23 to be lower than the rated voltage of the low voltage battery. For example, the control device 50 determines the terminal voltage or the SOC of the low voltage battery included in the second power source 12 based on the detected values from the sensors 62 and 63 on the second power source 12 side.

For example, the control device 50 determines, based on the current flowing through the interrupt switch 40, whether an overcurrent abnormality has occurred in which an excessive current flows through the electrical pathway 13, and turns off the interrupt switch 40 upon determining that the overcurrent abnormality has occurred. This can suppress a flow of overcurrent through the electrical pathway 13. Note that the overcurrent abnormality may occur due to a ground fault in which a portion of the electrical pathway 13 is short-circuited to the grounded portion, or due to runaway of an electrical load. For example, the control device 50 uses the detected value of the switch current sensor 64 as the current flowing through the interrupt switch 40.

The control device 50 includes a diagnosis unit 51. The diagnosis unit 51 diagnoses whether an ON failure has occurred in which the interrupt switch 40 remains stuck in the ON state after the switch is turned off. For example, the diagnosis unit 51 performs diagnosis of the interrupt switch 40 based on the detected value of the switch current sensor 64 and the detected value of the voltage sensor 62 on the second power source 12 side.

Incidentally, when the interrupt switch 40 is temporarily turned off during diagnosis of the interrupt switch 40, the supply of drive power from the second power source 12 to the first and second loads 31 and 32 is suspended. In such a case, for example, when the power output of the DC-DC converter 23 stops, the power supply from the first power source 11 to the first and second loads 31 and 32 may become insufficient. Thus, there is a concern that the operation of the first and second loads 31 and 32 may be unintentionally stopped.

Accordingly, the control device 50 includes a determination unit 52 and a command unit 53. The determination unit 52 determines whether the first power source 11 is in a power output state in which electric power is being supplied to the electrical pathway 13. The command unit 53 temporarily outputs an OFF-command to the interrupt switch 40 when performing the diagnosis of the interrupt switch 40, on condition that the first power source 11 is determined to be in the power output state.

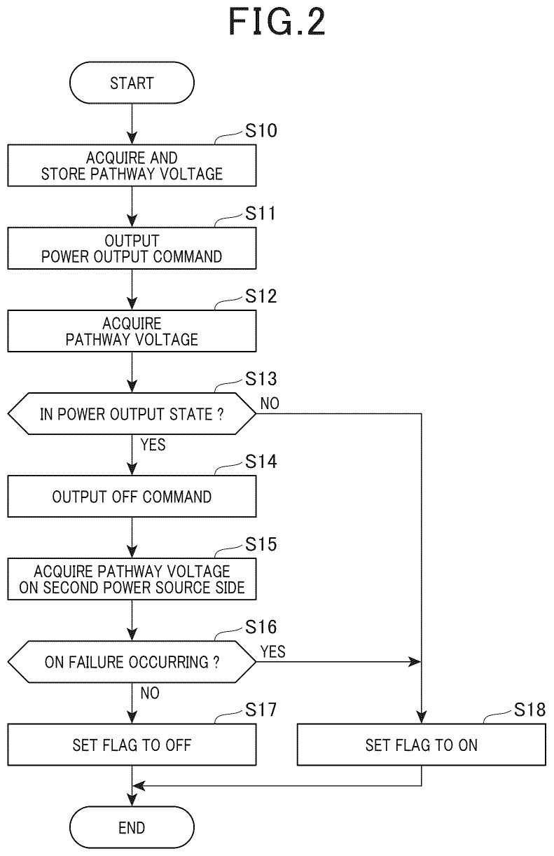

FIG. 2 illustrates a control process routine performed by the control device 50. This control is performed when a start switch is turned on. The start switch is, for example, an ignition switch or a push-type start switch, and is operated by a user of the vehicle.

Here, it is assumed that immediately after the start switch is turned on, the DC-DC converter 23 is not in operation, and drive power is being supplied to the loads 31 to 33 from the second power source 12.

At step S10, a path voltage of the electrical pathway 13 is acquired. Then, the acquired path voltage is stored in the memory of the control device 50. In this case, since the DC-DC converter 23 is not in operation immediately after the start switch is turned on, the path voltage of the electrical pathway 13 corresponds to the output voltage of the second power source 12.

At step S11, a power output command is output to the DC-DC converter 23 so that the output voltage of the DC-DC converter 23 becomes higher than the output voltage of the second power source 12. Specifically, the power output command to the DC-DC converter 23 is a drive command for switches included in the DC-DC converter 23.

At step S12, the path voltage of the electrical pathway 13 is acquired after the power output command is output. In this case, the path voltage of the electrical pathway 13 corresponds to the output voltage of the DC-DC converter 23. In the processes at steps S10 and S12, at least one of the detected value from the voltage sensor 60 on the first power source 11 side and the detected value from the voltage sensor 62 on the second power source 12 side may be used as the path voltage on the electrical pathway 13.

At step S13, it is determined whether the first power source 11 is in a power output state. In the present embodiment, it is determined whether the path voltage of the electrical pathway 13 has increased after the power output command is output. Specifically, it is determined whether a voltage rise value, calculated by subtracting the path voltage acquired at step S10 (i.e., the voltage stored in the memory) from the path voltage acquired at step S12, exceeds a predefined threshold. The threshold is a value greater than zero volts. If the answer is YES at step S13, the routine proceeds to step S14. If the answer is NO at step S13, the routine proceeds to step S18.

At step S14, an OFF-command is output to place the interrupt switch 40 in an OFF state for a predefined period.

At step S15, the path voltage of the electrical pathway 13 on the second power source 12 side after the OFF-command for the interrupt switch 40 is output is acquired. The detected value of the voltage sensor 62 on the second power source 12 side may be used as the path voltage of the electrical pathway 13 on the second power source 12 side. The diagnosis unit 51 performs the process at step S15 within a period of time immediately after the OFF-command for the interrupt switch 40 is output.

At step S16, it is determined whether an ON failure of the interrupt switch 40 has occurred, based on the path voltage of the electrical pathway 13 on the second power source 12 side. If it is determined at step S16 that no ON failure has occurred in the interrupt switch 40, the routine proceeds to step S17. On the other hand, if it is determined at step S16 that an ON failure has occurred in the interrupt switch 40, the routine proceeds to step S18.

For example, if no ON failure has occurred in the interrupt switch 40, it is expected that the interrupt switch 40 is actually turned off in response to the OFF-command output to the interrupt switch 40, and the path voltage of the electrical pathway 13 on the second power source 12 side returns to the value before the power output command was output. Therefore, when the absolute value of the difference between the path voltage acquired at step S15 and the path voltage acquired at step S10 is equal to or less than a predefined determination value, it is determined that no ON failure has occurred in the interrupt switch 40. On the other hand, if an ON failure has occurred in the interrupt switch 40, it is expected that the interrupt switch 40 is not actually turned off even after the OFF-command is output, and the path voltage of the electrical pathway 13 on the second power source 12 side remains at the value after the power output command is output. Therefore, the diagnosis unit 51 determines that an ON failure has occurred in the interrupt switch 40 when the absolute value of the difference between the path voltages acquired at steps S10 and S15 exceeds the determination value. Here, the determination value is, for example, a positive value that is close to zero.

It is to be noted that the method for determining the presence or absence of an ON failure in the interrupt switch 40 is not limited to the example described above. For example, a current flowing through the interrupt switch 40 may be acquired, and based on the acquired current, it may be determined whether an ON failure has occurred in the interrupt switch 40. In this case, it is determined that no ON failure has occurred in the interrupt switch 40 when the current flowing through the interrupt switch 40 after the OFF-command is output is less than a determination value. On the other hand, it is determined that an ON failure has occurred in the interrupt switch 40 when the current flowing through the interrupt switch 40 after the OFF-command is output is equal to or greater than the determination value. Here, the determination value is, for example, a value greater than zero. The current flowing through the interrupt switch 40 may be represented by the detected value of a switch current sensor 64.

At steps S17 and S18, a flag is set. For example, the flag is transmitted from the control device 50 to a higher-level control device and is used to determine whether transition to an autonomous driving mode is permitted. Specifically, when the flag is OFF, the transition to the autonomous driving mode is permitted; whereas, when the flag is ON, the transition to the autonomous driving mode is inhibited. At step S17, the flag is set to OFF. On the other hand, at step S18, the flag is set to ON.

In some embodiments, a higher-level control device may perform a process of notifying the user that an ON failure has occurred in the interrupt switch 40 when the flag is ON.

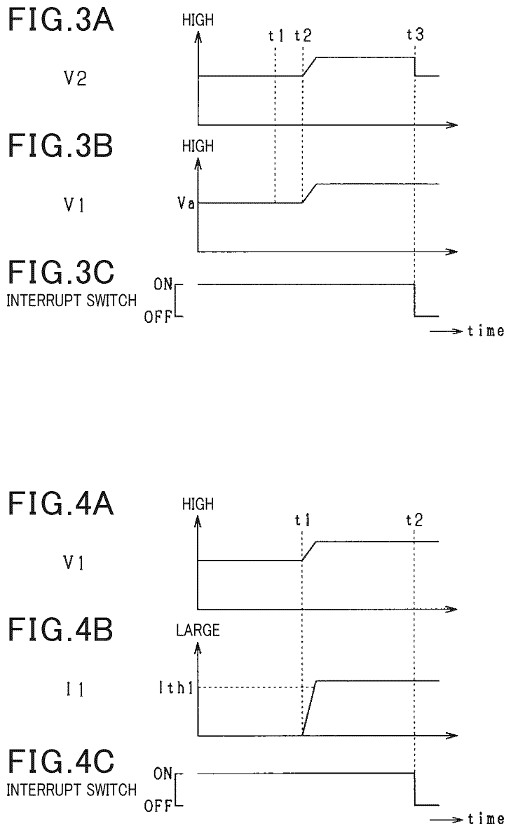

FIGS. 3A-3C illustrate an example of control performed by the control device 50. The example illustrated in FIGS. 3A-3C represents a case in which no ON failure has occurred in the interrupt switch 40. FIG. 3A shows a course of voltage V2 of the electrical pathway 13 on the second power source 12 side of the interrupt switch 40. FIG. 3B shows a course of voltage V1 of the electrical pathway 13 on the first power source 11 side of the interrupt switch 40. FIG. 3C shows the ON/OFF state of the interrupt switch 40. In FIGS. 3A-3C, it is assumed that no power output from the first power source 11 occurs before time t1.

At time t1, the control device 50 acquires the path voltage of the electrical pathway 13 and stores the acquired voltage value Va in the memory. At time t2, the control device 50 outputs the power output command to the DC-DC converter 23. As a result, the voltage V1 on the first power source 11 side and the voltage V2 on second power source 12 side increase.

At time t3, the control device 50 acquires the path voltage of the electrical pathway 13 after the power output command is output, and determines that the voltage rise value calculated by subtracting the voltage value Va stored in the memory from the acquired voltage value is greater than a threshold. In response thereto, the control device 50 outputs the OFF-command to the interrupt switch 40. As a result, the interrupt switch 40 is turned off, and the voltage V2 on the second power source 12 side returns to the value before the power output command was output. After the OFF-command to the interrupt switch 40 is output, the control device 50 acquires the detected value from the voltage sensor 62 on the second power source 12 side. Based on the acquired detected value from the voltage sensor 62 on the second power source 12 side, the control device 50 determines whether an ON failure has occurred in the interrupt switch 40, and sets a fault flag to ON or OFF according to the result of the determination.

The present embodiment, as detailed above, can provide the following advantages.

Whether the first power source 11 is in the power output state in which power is supplied to the electrical pathway 13 is determined, and when performing the diagnosis of the interrupt switch 40, the OFF-command is temporarily output to the interrupt switch 40 on condition that it has been determined that the first power source 11 is in the power output state. In this case, the drive power for the first load 31 and the second load 32 is ensured while the interrupt switch 40 is off. As a result, unintended power loss to the first load 31 and the second load 32 can be suppressed, and interruption of the operation of the first load 31 and the second load 32 can be prevented.

Whether the first power source 11 is in the power output state is determined based on the path voltage of the electrical pathway 13. Specifically, when the path voltage of the electrical pathway 13 increases after the power output command is output, it is determined that the first power source 11 is in the power output state. This enables accurate determination as to whether the first power source 11 is in the power output state.

### Modifications of First Embodiment

In the process at step S13 in FIG. 2, the method for determining whether the first power source 11 is in the power output state may be modified. Here, a determination method using the output current of the first power source 11 will be described.

At step S13, the output current of the first power source 11 is acquired, and if it is determined that the output current of the first power source 11 exceeds a predefined threshold current Ith1, the first power source 11 is determined to be in the power output state. The detected value of the current sensor 61 provided on the first power source 11 side may be used as the output current of the first power source 11. On the other hand, if it is determined that the output current of the first power source 11 is equal to or less than the threshold current Ith1, the first power source 11 is determined not to be in the power output state. For example, the threshold current Ith1 is a value greater than zero.

FIGS. 4A-4C illustrate an example of control performed by the control device 50 according to the present embodiment. FIG. 4B shows a course of output current I1 of the first power source 11. FIGS. 4A and 4C correspond to FIGS. 3B and 3C, respectively.

At time t1, the control device 50 outputs the power output command to the DC-DC converter 23. As a result, the voltage V1 of the electrical pathway 13 on the first power source 11 side of the interrupt switch 40, and the output current I1 of the first power source 11, increase. At time t2, the control device 50 determines that the output current of the first power source 11 exceeds the threshold current Ith1. In response thereto, the control device 50 outputs the OFF-command to the interrupt switch 40. The interrupt switch 40 is thereby turned off.
The diagnosis of the interrupt switch 40 may be performed using the current flowing to the second power source 12.

At step S13, the current flowing to the second power source 12 is acquired. Here, the current flowing in the direction in which the low voltage battery of the second power source 12 is charged is regarded as positive, and the current flowing in the direction in which the low-voltage battery discharges is regarded as negative, and the current flowing to the second power source 12 is acquired accordingly. If it is determined that the current flowing to the second power source 12 exceeds a predefined threshold current Ith2, the first power source 11 is determined to be in the power output state. The threshold current Ith2 is set, for example, to a value equal to or greater than zero. That is, the threshold current Ith2 is set to a value that allows a determination to be made that current is flowing through the electrical pathway 13 from the first power source 11 to the second power source 12. The detected value of the current sensor 63 provided on the second power source 12 side is used as the current flowing to the second power source 12.

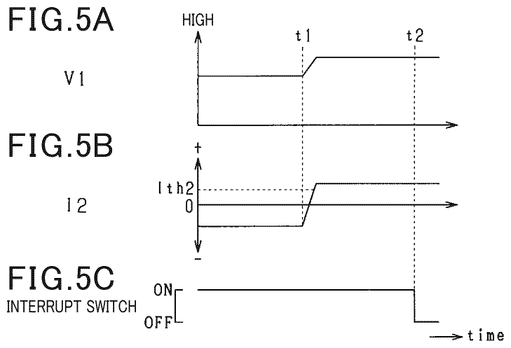

FIG. 5A-5C illustrate an example of control performed by the control device 50 according to the present embodiment. FIG. 5B shows a course of current I2 flowing to the second power source 12. FIGS. 5A and 5C correspond to FIGS. 4A and 4C, respectively.

At time t1, the control device 50 outputs the power output command to the DC-DC converter 23. As a result, the voltage V1 of the electrical pathway 13 on the first power source 11 side of the interrupt switch 40, and the current I2 flowing to the second power source 12, increase. At time t2, the control device 50 determines that the current flowing to the second power source 12 exceeds the threshold current Ith2. In response thereto, the control device 50 outputs the OFF-command to the interrupt switch 40. The interrupt switch 40 is thereby turned off.

According to the present embodiment, the detected value of the current sensor 63 on the second power source 12 side is used to determine whether the first power source 11 is in the power output state. The detected value of the current sensor 63 on the second power source 12 side is also used, for example, to detect the state of charge (SOC) of the low-voltage battery included in the second power source 12. In this case, the diagnosis of the interrupt switch 40 can be performed while suppressing an increase in the number of sensors provided in the power supply system.
The diagnosis of the interrupt switch 40 may be performed using the current flowing through the interrupt switch 40. In this case, at step S13, the same process as the diagnosis of the interrupt switch 40 using the current flowing to the second power source 12, as described above, is performed. The detected value of the switch current sensor 64 may be used as the current flowing through the interrupt switch 40. It is to be noted that, if FIG. 5B is regarded as illustrating a course of the current flowing through the interrupt switch 40, the example of control performed by the control device 50 according to the present embodiment is the same as that illustrated in FIG. 5.

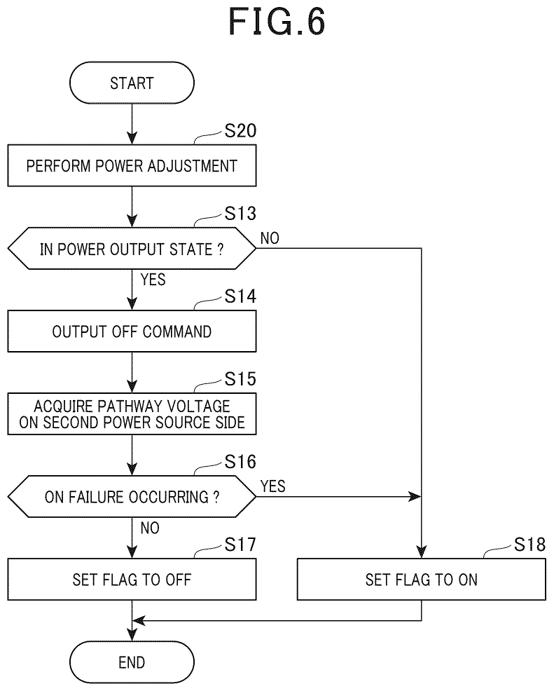

According to the present embodiment, the detected value of the switch current sensor 64 is used to determine whether the first power source 11 is in the power output state. The detected value of the switch current sensor 64 is also used, for example, to detect an overcurrent abnormality. In this case, the diagnosis of the interrupt switch 40 can be performed while suppressing an increase in the number of sensors provided in the power supply system.
In the process at step S13 in FIG. 2, the first power source 11 may be determined to be in the power output state when the path voltage of the electrical pathway 13 exceeds a predefined threshold voltage. In this case, the process at step S10 may be omitted. The threshold voltage is, for example, a value higher than the rated voltage of the low-voltage battery included in the second power source 12.
In the process at step S13 in FIG. 2, the determination as to whether the first power source 11 is in the power output state may be performed using at least two of the followings: the path voltage of the electrical pathway 13, the output current of the first power source 11, the current flowing to the second power source 12, and the current flowing through the interrupt switch 40.
In the process at step S13 in FIG. 2, the first power source 11 may be determined to be in the power output state when it is determined that the power output command for the DC-DC converter 23 has been output. In this case, the processes at steps S10 and S12 may be omitted.
In the present embodiment, the control device 50 performs the control illustrated in FIG. 6. This control is performed at predefined intervals, instead of being performed in response to the start switch being turned on. Here, a situation is assumed in which the vehicle is running and the diagnosis of the interrupt switch 40 is performed while the DC-DC converter 23 is in operation. In FIG. 6, steps identical to those illustrated in FIG. 2 are denoted by the same step numbers for convenience.

In the present embodiment, instead of performing the processes at steps S10 to S12 in FIG. 2, the process at step S20 is performed, as illustrated in FIG. 6. At step S20, the magnitude of the power output from the first power source 11 is adjusted according to the power requirements of the first and second loads 31 and 32, which are connected to the electrical pathway 13 on the first power source 11 side of the interrupt switch 40. Specifically, the higher the power requirements of the first and second loads 31 and 32, the higher the output voltage setpoint of the DC-DC converter 23 is set. The process at step S20 corresponds to a power adjustment unit.

At step S13, a determination is made as to whether the first power source 11 is in the power output state, using at least one of: the output current of the first power source 11, the current flowing to the second power source 12, and the current flowing through the interrupt switch 40.

According to the present embodiment, the higher the power requirements of the first and second loads 31 and 32, the higher the output voltage setpoint of the DC-DC converter 23 is set. As a result, even if the power requirements of the first and second loads 31 and 32 increase, it is possible to supply drive power from the first power source 11 to the first and second loads 31 and 32. Therefore, during the diagnosis of the interrupt switch 40, it is possible to reliably suppress occurrence of a situation in which the supply of drive power from the first power source 11 to the first and second loads 31 and 32 becomes insufficient.
In the process at step S13 in FIG. 2, the determination condition for determining whether the first power source 11 is in the power output state may be modified.

On the first power source 11 side of the interrupt switch 40 in the electrical pathway 13, it is conceivable that the power requirement of at least one of the first load 31 and the second load 32 may vary, and in order to ensure the operation of the first and second loads 31 and 32, it is desirable to define a determination condition for determining whether power supply from the first power source 11 to the first and second loads 31 and 32 is appropriate, taking into account variations in power requirement. Furthermore, if the determination condition is too strict, there is a concern that opportunities to perform diagnosis of the interrupt switch 40 may be unnecessarily reduced.

Accordingly, the determination unit 52 changes the determination condition for determining whether the first power source 11 is in the power output state, according to the power requirements of the first and second loads 31 and 32 connected to the electrical pathway 13 on the first power source 11 side of the interrupt switch 40.

Specifically, at step S13 in FIG. 2, the determination condition is adjusted toward higher output power of the first power source 11 as at least one of the power requirements of the first load 31 and the second load 32 increases. For example, when determining the power output state based on the voltage rise value between before and after the power output command is output to the DC-DC converter 23, the threshold used for the determination is set higher as the total power requirement of the loads 31 and 32 increases.

According to the present embodiment, the configuration is such that the determination condition for determining whether the first power source 11 is in the power output state is changed according to at least one of the power requirements of the respective loads 31 and 32. This makes it possible to perform appropriate failure diagnosis while taking into account potential variations in the power requirements of the loads 31 and 32.
It is possible to adopt a configuration in which the third load 33 is not disposed along the electrical pathway 13.

### Second Embodiment

In a second embodiment, energization of the second load 32 is restricted when performing diagnosis of the interrupt switch 40.

In the present embodiment, the first load 31 is regarded as a load whose continued operation is prioritized over the second load 32 during diagnosis of the interrupt switch 40. For example, the first load 31 is an electrical load that requires continuation of at least some functions of the ECU, etc. for a long period of time, and the second load 32 is a general electrical load. In this case, there is a concern that, when diagnosis of the interrupt switch 40 is performed, the operation of the second load 32 may lead to insufficient power supply to the first load 31. In view of the forgoing, in the present embodiment, energization of the second load 32 is restricted during diagnosis of the interrupt switch 40.

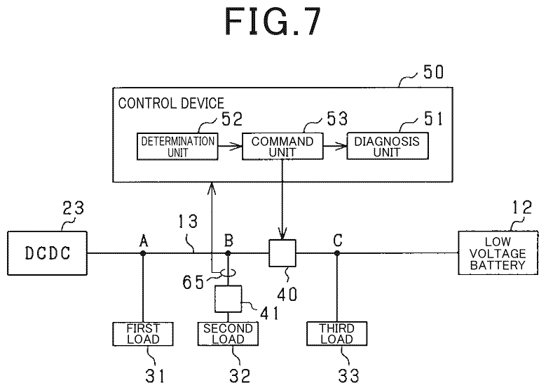

As illustrated in FIG. 7, the power supply system includes a load switch 41. The load switch 41 is a normally closed switch and is constituted by, for example, a relay or a semiconductor switch such as a MOSFET. The load switch 41 is provided in an electrical pathway connecting a connection point B of the second load 32 and the positive terminal side of the second load 32. The control device 50 restricts energization of the second load 32 by turning off the load switch 41 prior to outputting the OFF-command to the interrupt switch 40. It should be noted that, in FIG. 7, components identical to those illustrated in FIG. 1 are denoted by the same reference numerals for convenience, and some components are omitted from illustration.

The power supply system includes a load current sensor 65 that detects a current flowing through the load switch 41. The load current sensor 65 detects the current using, for example, a shunt resistor or a Hall element.

The command unit 53 does not output the OFF-command to the interrupt switch 40 when restriction of energization of the second load 32 is determined to be unavailable. For example, the command unit 53 acquires a current flowing through the load switch 41 in the OFF state, and when the acquired current value is equal to or greater than a predefined value, determines that restriction of energization of the second load 32 is unavailable, and refrains from outputting the OFF-command to the interrupt switch 40. A detected value from the load current sensor 65 can be used as the current flowing through the load switch 41. It should be noted that an example of a situation in which restriction of energization of the second load 32 is unavailable is a case where an ON failure has occurred in the load switch 41.

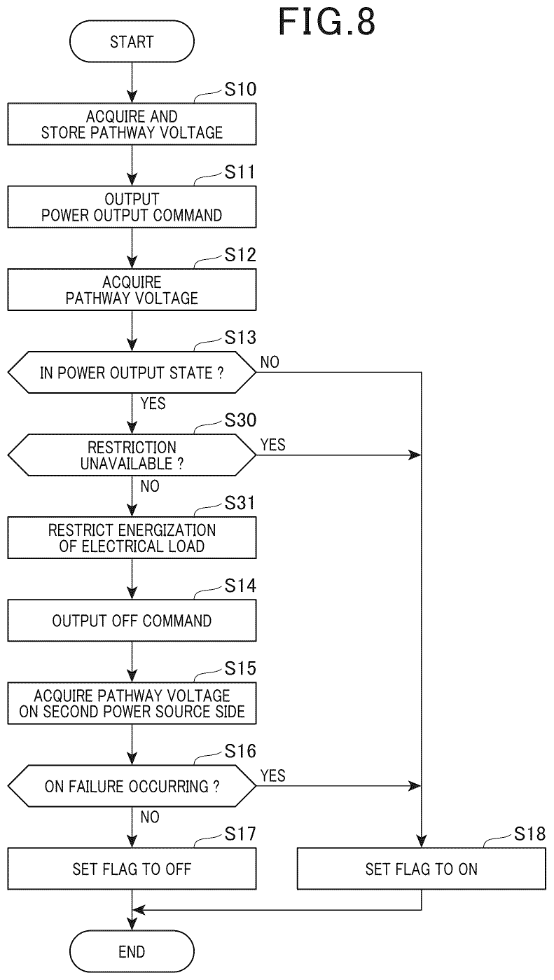

As illustrated in FIG. 8, at step S30, it is determined whether restriction of energization of the second load 32 is unavailable. If the answer is NO at step S30, the routine proceeds to step S31. At step S31, when performing diagnosis of the interrupt switch 40, energization of the second load 32 is restricted by turning off the load switch 41 prior to outputting the OFF-command to the interrupt switch 40. On the other hand, if the answer is YES at step S30, the routine proceeds to step S18. That is, when it is determined that restriction of energization of the second load 32 is unavailable, the OFF-command is not output to the interrupt switch 40. It should be noted that the process at step S31 corresponds to an energization restriction unit. In FIG. 8, steps identical to those illustrated in FIG. 2 are denoted by the same step numbers for convenience.

Restricting energization of the second load 32 when performing diagnosis of the interrupt switch 40 allows supply of drive power from the first power source 11 to the first load 31 to be prioritized over supply of drive power to the second load 32 while the interrupt switch 40 is in the OFF state. This makes it possible to reliably prevent insufficient power supply to the first load 31.

The configuration is such that, in a case where, prior to performing diagnosis of the interrupt switch 40, it is determined that restriction of energizing the second load 32 is unavailable, no OFF-command is output to the interrupt switch 40. With this configuration, in a situation where there is a concern that drive power supply to the first load 31 may become insufficient, the diagnosis of the interrupt switch 40 is not to be performed.

### Modifications of Second Embodiment

At step S31 of FIG. 8 described above, instead of turning off the load switch 41, energization of the second load 32 may be restricted by suspending the operation of the second load 32 or reducing the power requirement of the second load 32. At step S31 in FIG. 8, energization of the second load 32 is restricted according to the power requirements of the respective loads 31 and 32, which are connected to the electrical pathway 13 on the first power source 11 side of the interrupt switch 40. For example, energization of the second load 32 is restricted when the total power requirement of the loads 31 and 32 is equal to or greater than a predefined amount of power, and energization of the second load 32 is not restricted when the total power requirement falls below the predefined amount of power. With this configuration, in situations where insufficient power supply to the first load 31 is unlikely to occur, unnecessary restriction of functions of the second load 32 can be prevented.
The process at step S30 in FIG. 8 described above may be omitted.

### Third Embodiment

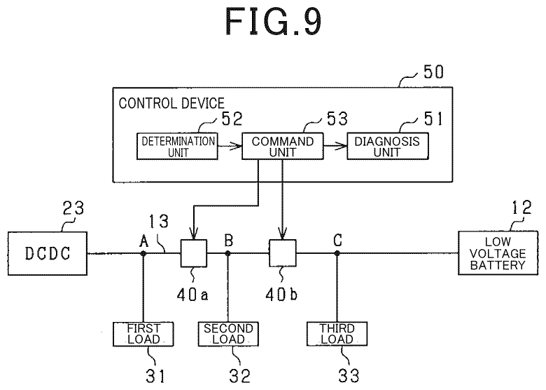

In a third embodiment, the configuration of the power supply system is modified from the first embodiment. As illustrated in FIG. 9, in the present embodiment, interrupt switches 40 are provided at multiple positions in the electrical pathway 13 between the respective connection points of the loads 31 to 33. That is, the interrupt switches 40 are provided:
at a position between the connection points A and B of the loads 31 and 32 in the electrical pathway 13; and
at a position between the connection points B and C of the loads 32 and 33 in the electrical pathway 13. In FIG. 9, the interrupt switch 40 provided between the connection points A and B in the electrical pathway 13 is denoted as interrupt switch 40a, and the interrupt switch 40 provided between the connection points B and C is denoted as interrupt switch 40b. It should be noted that, in FIG. 9, components identical to those illustrated in FIG. 1 are denoted by the same reference numerals for convenience, and some components are omitted from illustration.

The command unit 53 temporarily outputs OFF-commands to the plurality of interrupt switches 40a and 40b provided in the electrical pathway 13. In the present embodiment, the command unit 53, when performing diagnosis of each of the interrupt switches 40a and 40b, outputs the OFF-command to each of the interrupt switches 40a and 40b, one at a time, as a subject of OFF control. For example, the command unit 53 outputs the OFF-command with the interrupt switch 40a as a subject of OFF control, and after diagnosis of the interrupt switch 40a is completed, outputs the OFF-command with the interrupt switch 40b as a subject of OFF control.

In the above configuration, the first load 31 is connected to the electrical pathway 13 on the first power source 11 side of the interrupt switch 40a, while the first and second loads 31 and 32 are connected to the electrical pathway 13 on the first power source 11 side of the interrupt switch 40b. In this case, when the interrupt switch 40b is turned off, it is considered that the possibility of an insufficient supply of drive power from the first power source 11 to the first and second loads 31 and 32 increases, as compared to the case where the interrupt switch 40a is turned off, due to a larger number of electrical loads being connected to the electrical pathway 13 on the first power source 11 side.

Accordingly, the determination unit 52 changes the determination condition for determining whether the first power source 11 is in the power output state, according to the number of electrical loads connected to the electrical pathway 13 on the first power source 11 side of the interrupt switch 40 that is the subject of OFF control by the command unit 53.

Specifically, when the interrupt switch 40b is the subject of OFF control, the determination unit 52 changes the determination condition such that the output power of the first power source 11 becomes higher, as compared to the case where the interrupt switch 40a is the subject of OFF control. For example, when the determination unit 52 determines the power output state using a voltage rise value between before and after the power output command is output to the DC-DC converter 23, the threshold used to determine whether the first power source 11 is in the power output state is set higher as the number of electrical loads connected to the electrical pathway 13 on the first power source 11 side of the interrupt switch 40, which is the subject of OFF control, increases.

According to the present embodiment, the configuration is such that the determination condition for determining whether the first power source 11 is in the power output state is changed according to the number of electrical loads connected to the electrical pathway 13 on the first power source 11 side of the interrupt switch 40 that is the subject of OFF control, among the interrupt switches 40a and 40b. This makes it possible to perform appropriate failure diagnosis while taking into account the fact that the power requirement of the electrical loads varies with the number of connected loads.

### Other Embodiments

Each of the above embodiments may be modified as follows.
The configuration of the first power source 11 may be modified. For example, the first power source 11 may be a rechargeable battery capable of being charged and discharged.
The interrupt switch 40 and the load switch 41 are not necessarily normally closed switches.
The power supply system may be mounted to a mobile object other than a vehicle. Alternatively, the power supply system may be a stationary system.
The control device and the method thereof described in the present disclosure may be realized by a dedicated computer provided by configuring a processor and memory programmed to perform one or more functions embodied in a computer program. Alternatively, the control device and the method thereof described in the present disclosure may be realized by a dedicated computer provided by configuring a processor with one or more dedicated hardware logic circuits. Alternatively, the control device and the method thereof described in the present disclosure may be realized by one or more dedicated computers configured by a combination of a processor and memory programmed to perform one or more functions, and a processor configured with one or more hardware logic circuits. In addition, the computer program may be stored in a computer-readable, non-transitory tangible storage medium as instructions to be executed by a computer.

Although the present disclosure has been described in accordance with the above-described embodiments, it is not limited to such embodiments, but also encompasses various variations and variations within equal scope. In addition, various combinations and forms, as well as other combinations and forms, including only one element, more or less, thereof, are also within the scope and idea of the present disclosure.

What is claimed is:

1. A switch control device for a power supply system equipped with a first power source and a second power source connected via an electrical pathway, an electrical load connected to the electrical pathway and capable of being supplied with power from the first power source and the second power source, and a switch provided between the second power source and a connection point along the electrical pathway where the electrical load is connected to the electrical pathway, the switch control device being configured to diagnose an ON failure of the switch by turning off the switch, and comprising:
a determination unit configured to determine whether the first power source is in a power output state in which it is outputting power to the electrical pathway; and
a command unit configured to temporarily output an OFF-command to the switch when performing diagnosis of the ON failure, on condition that the first power source is determined to be in the power output state.

2. The switch control device according to claim 1, wherein
the determination unit is configured to determine whether the first power source is in the power output state, based on at least one of a pathway voltage of the electrical pathway, an output current of the first power source, and a direction of current flowing through the electrical pathway.

3. The switch control device according to claim 1, wherein
the determination unit is configured to change a determination condition for determining whether the first power source is in the power output state according to a power requirement of the electrical load connected to the electrical pathway on a first power source side of the switch.

4. The switch control device according to claim 1, wherein
a plurality of the electrical loads are connected to the electrical pathway, and
the switches are provided at multiple positions between connection points of the plurality of the electrical loads, one switch between each pair of the adjacent connection points,
the command unit is configured to output the OFF-command to each of the plurality of switches provided in the electrical pathway, one at a time, when performing diagnosis of the ON failure, and
the determination unit is configured to change a determination condition for determining whether the first power source is in the power output state, according to a number of electrical loads connected to the electrical pathway on the first power source side of the switch, among the plurality of the switches, to be turned off by the command unit.

5. The switch control device according to claim 1, further comprising
an energization restriction unit configured to, when performing diagnosis of the ON failure, restrict energization of the electrical load connected to the electrical pathway on the first power source side of the switch, prior to the command unit outputting the OFF-command to the switch.

6. The switch control device according to claim 5, wherein
the energization restriction unit is configured to restrict energization of the electrical load connected to the electrical pathway on the first power source side of the switch, according to a power requirement of the electrical load.

7. The switch control device according to claim 5, wherein
the command unit is configured to not output the OFF-command to the switch when restriction of energization by the energization restriction unit is determined to be unavailable.

8. The switch control device according to claim 1, wherein
the first power source is configured to be capable of adjusting a magnitude of power output to the electrical pathway, and
the switch control device further comprises a power adjustment unit configured to, when performing diagnosis of the ON failure, change a magnitude of power output from the first power source according to a power requirement of the electrical load connected to the electrical pathway on the first power source side of the switch.

9. A program product comprising:
a non-transitory computer-readable medium;
instructions stored on the non-transitory computer-readable medium that, when executed by a processor, cause the processor to perform a switch control method applied to a power supply system equipped with a first power source and a second power source connected via an electrical pathway, an electrical load connected to the electrical pathway and capable of being supplied with power from the first power source and the second power source, and a switch provided between the second power source and a connection point along the electrical pathway where the electrical load is connected to the electrical pathway, the switch control method being performed to diagnose an ON failure of the switch by turning off the switch, and comprising:
determining whether the first power source is in a power output state in which it is outputting power to the electrical pathway; and
when performing diagnosis of the ON failure, temporarily outputting an OFF-command to the switch on condition that the first power source is determined to be in the power output state.

10. A non-transitory computer-readable medium storing instructions that, when executed by a processor, cause the processor to perform a switch control method applied to a power supply system equipped with a first power source and a second power source connected via an electrical pathway, an electrical load connected to the electrical pathway and capable of being supplied with power from the first power source and the second power source, and a switch provided between the second power source and a connection point along the electrical pathway where the electrical load is connected to the electrical pathway, the switch control method being performed to diagnose an ON failure of the switch by turning off the switch, and comprising:
determining whether the first power source is in a power output state in which it is outputting power to the electrical pathway; and
when performing diagnosis of the ON failure, temporarily outputting an OFF-command to the switch on condition that the first power source is determined to be in the power output state.
